(19) United States
(12) Patent Application Publication
(10) Pub. No.: US 2013/0342170 A1
(43) Pub. Date: Dec. 26, 2013

(54) BATTERY DISCHARGE DEVICE FOR REUSING DISCHARGE ENERGY AND METHOD USING BATTERY DISCHARGE DEVICE

(71) Applicant: LG CNS CO., LTD., (US)

(72) Inventors: Inchol Yeon, Gyeonggi-do (KR); Tae Hyoung Ryu, Seoul (KR); Cheol Kyu Han, Incheon (KR); Dong Hoon Shin, Incheon (KR)

(73) Assignee: LG CNS CO., LTD., Seoul (KR)

(21) Appl. No.: 13/692,243

(22) Filed: Dec. 3, 2012

(30) Foreign Application Priority Data
Dec. 20, 2011 (KR) 10-2011-0138003

(51) Int. Cl. G01R 31/36

(52) U.S. Cl. CPC G01R 31/3606
USPC 320/135

(57) ABSTRACT

A battery discharge device may include an accommodation unit to accommodate a battery, a controller to control a switch connected to the battery so that a first alternating current (AC) power is generated based on a discharge profile and a first direct current (DC) power discharged from the battery, a transformation unit to generate, based on the first AC power, a second AC power having a voltage higher than a voltage of the first AC power, and a rectification unit to generate a second DC power, based on the second AC power.

### CROSS-REFERENCE TO RELATED APPLICATION

This application claims the benefit of Korean Patent Application No. 10-2011-0138003, filed on Dec. 20, 2011, in the Korean Intellectual Property Office, the disclosure of which is incorporated herein by reference.

### BACKGROUND

1. Field of the Invention

The following embodiments of the present invention relate to a battery discharge device that may reuse discharge energy, and a method using the battery discharge device.

2. Description of the Related Art

To verify performance of batteries in a battery production line, a test of discharging batteries based on a discharge profile is performed. In this instance, a large amount of current may be discharged through a transistor. As a result, the transistor may generate a large amount of heat, and a cooling system used to cool the transistor may need to be operated to prevent the transistor from being damaged. In other words, electric energy discharged by the test of discharging batteries is consumed in the form of thermal energy generated in a transistor that functions as a switch.

### SUMMARY

According to an aspect of the present invention, there is provided a battery discharge device used in a discharge system that induces a discharge of a battery based on a discharge profile, including: an accommodation unit to accommodate at least one battery; a switch unit connected to the at least one battery accommodated in the accommodation unit, to generate a first alternating current (AC) power from a first direct current (DC) power discharged from the at least one battery based on the discharge profile; a transformation unit to generate a second AC power based on the first AC power, the second AC power having a voltage higher than a voltage of the first AC power; and a rectification unit to generate a second DC power based on the second AC power, the second DC power having a voltage higher than a voltage of the first DC power.

The switch unit may include a controller to control a magnitude of the first AC power using a pulse waveform generated based on the discharge profile.

The switch unit may further include a high-current driving transistor to generate the first AC power from the first DC power. The high-current driving transistor may be operated by the pulse waveform.

The transformation unit may include a primary inductor and a secondary inductor. The primary inductor may accommodate the first AC power, and the secondary inductor may generate the second AC power based on the first AC power and a turns ratio between the primary inductor and the secondary inductor.

Each of the primary inductor and the secondary inductor may be suitable to be operated when the turns ratio is equal to or greater than a predetermined value.

The battery discharge device may further include an output unit to accommodate the second DC power, to add up a current of the accommodated second DC power, and to output the added current.

According to another aspect of the present invention, there is provided a battery discharge method used in a discharge system that induces a discharge of a battery based on a discharge profile, including: reading the discharge profile from a memory storage device in which the discharge profile is stored; generating a first AC power from a first DC power discharged based on the discharge profile from at least one battery included in the discharge system; generating a second AC power based on the first AC power, the second AC power having a voltage higher than a voltage of the first AC power; and generating a second DC power based on the second AC power, the second DC power having a voltage higher than a voltage of the first DC power.

The generating of the first AC power may include controlling a magnitude of the first AC power, using a pulse waveform generated based on the discharge profile, and using a high-current driving transistor operated by the pulse waveform.

A ratio of the voltage of the second DC power to the voltage of the first DC power may be equal to or greater than a predetermined value.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating a conventional prior-art charge and discharge system;

FIG. 2 is a block diagram illustrating a battery discharge device used in a discharge system that induces a discharge of a battery based on a discharge profile according to an embodiment of the present invention; and

FIG. 3 is a flowchart illustrating a battery discharge method used in a discharge system that induces a discharge of a battery based on a discharge profile according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

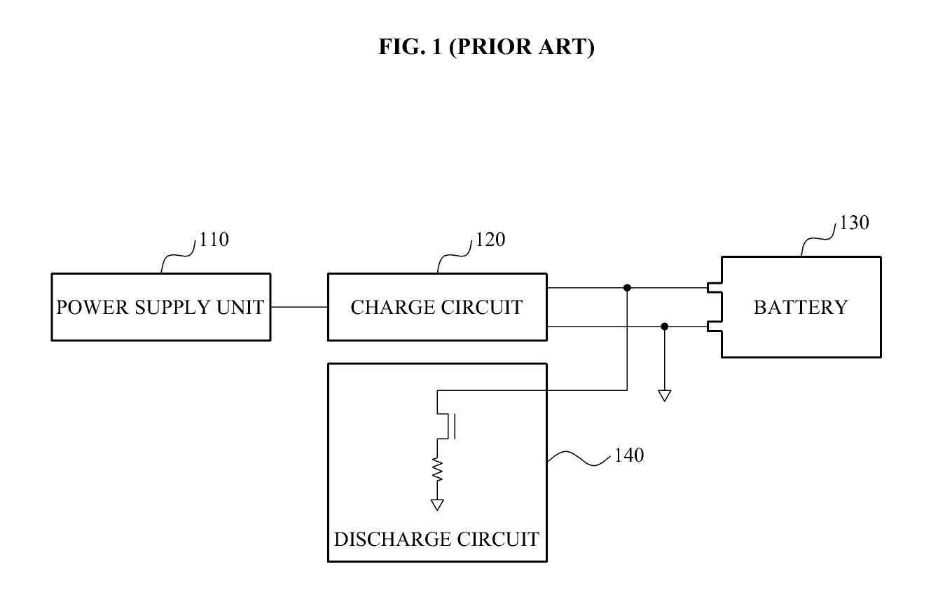

FIG. 1 is a block diagram illustrating a conventional prior-art charge and discharge system.

Referring to FIG. 1, the conventional prior-art charge and discharge system may include a power supply unit 110, a charge circuit 120, a battery 130, and a discharge circuit 140.

The charge circuit 120 may receive power from the power supply unit 110, to charge the battery 130. The charge circuit 120 may perform a test of charging the battery 130 using the received power at various charge rates, for example C/2, C, 2C, and the like.

For example, in a battery with a capacity of 1.6 ampere-hours (Ah), C may be 1.6 ampere (A). In this instance, when a test is performed based on a charge rate of 2 C (=3.2 A), the conventional charge and discharge system may determine whether the battery 130 sufficiently absorbs electric charges provided by the charge circuit 120 to complete charging of the battery 130 within 30 minutes.

Additionally, the discharge circuit 140 may include a transistor, and a gate voltage controller. In this instance, the gate voltage controller may control a magnitude of voltage applied to a gate of the transistor, and may control discharging of the battery 130.

For example, when voltage between a drain and a source of a metal-oxide-semiconductor field-effect transistor (MOSFET) is relatively low, and when voltage between the drain and a gate of the MOSFET exceeds threshold voltage, an inversion layer of the MOSFET may have the same function as a resistance. A region in which the MOSFET performs the above operation may be called a “linear region.” In the linear region, the inversion layer may be thickened in proportion to gate voltage of the MOSFET, and accordingly a resistance between the drain and the source of the MOSFET may be reduced.

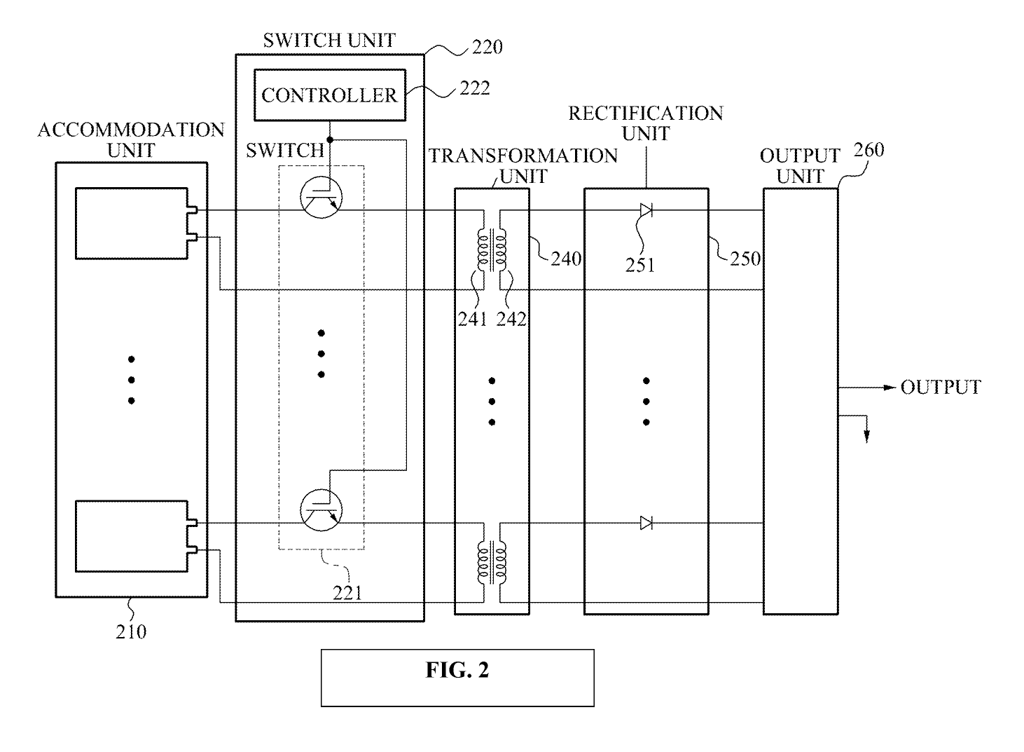

FIG. 2 is a block diagram illustrating a battery discharge device used in a discharge system that induces a discharge of a battery based on a discharge profile according to an embodiment of the present invention.

Referring to FIG. 2, the battery discharge device may include an accommodation unit 210, a switch unit 220, a transformation unit 240, a rectification unit 250, and an output unit 260.

The accommodation unit 210 may accommodate at least one battery. The switch unit 220 may be connected to the at least one battery accommodated in the accommodation unit 210, and may control a flow of current discharged from the at least one battery. Specifically, the switch unit 220 may generate a first alternating current (AC) power from a first direct current (DC) power discharged from the at least one battery based on the discharge profile.

In this instance, the switch unit 220 may include a high-current driving transistor. For example, the battery discharge device may implement at least one switch 221, using the high-current driving transistor. In this example, the battery discharge device may use, as the high-current driving transistor, an insulated-gate bipolar transistor (IGBT).

The IGBT may be a high-power switching semiconductor that may quickly perform a switching operation that blocks a flow of electricity or that enables electricity to flow. The switching function may be implemented by other parts or circuits. However, a product requiring a more precise operation may require a higher operation speed and lower power dissipation. Specifically, an existing switching semiconductor, namely a transistor, is inexpensive, but has a complex circuit configuration and is operated at low speed. Additionally, a MOSFET is operated at low power and high speed, but is expensive. The IGBT may guarantee a high operation speed at low cost.

The switch unit 220 may further include a controller 222. The controller 222 may control a magnitude of the first AC power, using a pulse waveform generated based on the discharge profile. Specifically, the controller 222 may control at least one switch connected to the at least one battery in the accommodation unit 210, so that the at least one battery may be discharged based on the discharge profile, and that the first AC power may be generated from the first DC power.

In this instance, the discharge profile may be information regarding a form in which a battery is discharged over time. The discharge profile used in the battery discharge device may be a discharge profile used to verify performance of an electric vehicle battery. For example, an electric vehicle may travel into the heart of a city, on a highway, on a sloping road, and the like. In this example, the electric vehicle battery may need to provide current corresponding to the above traveling of the electric vehicle. Accordingly, the discharge profile used in the battery discharge device may be a discharge profile provided by an electric vehicle manufacturing company, or a discharge profile used in a test of determining whether a specification of a battery required by the electric vehicle manufacturing company is satisfied.

The controller 222 may include a gate voltage controller to control a magnitude of voltage applied to a gate of the high-current driving transistor, by using a pulse waveform, based on the discharge profile. For example, the gate voltage controller may control a magnitude of voltage applied to a gate of the IGBT, using a pulse waveform, and may generate first AC power that switches first DC power discharged from the at least one battery to a pulse waveform. In this instance, the gate voltage controller may take into consideration whether the at least one battery is to be discharged based on the discharge profile, a discharge speed at which DC power is discharged from the at least one battery, a discharge form, and the like.

Specifically, the controller 222 may control a form in which the at least one battery in the accommodation unit 210 is discharged, based on the discharge profile, and may verify performance of the at least one battery. In this instance, the controller 222 may macroscopically depend on the discharge profile. To generate the first AC power, the controller 222 may microscopically control the first DC power discharged from the at least one battery to be switched to a pulse waveform.

The battery discharge device may reduce an amount of heat generated in the at least one switch 221, by discharging a battery using a pulse waveform. Furthermore, to prevent the at least one switch 221 from being damaged, the battery discharge device may reduce energy consumed to cool the at least one switch 221, by reducing the amount of the heat generated in the at least one switch 221.

Additionally, the transformation unit 240 in the battery discharge device may generate second AC power, based on the first AC power. Voltage of the second AC power may be higher than voltage of the first AC power.

The transformation unit 240 may include a primary inductor 241 and a secondary inductor 242. The primary inductor 241 may store the first AC power, and the secondary inductor 242 may generate second AC power having voltage higher than the voltage of the first AC power, based on the first AC power and a turns ratio between the primary inductor 241 and the secondary inductor 242.

Specifically, the transformation unit 240 may transfer electric energy from a primary side to a secondary side, using the primary inductor 241 and the secondary inductor 242 that are inductive electric conductors. For example, magnetic flux may be formed by current changed to a pulse waveform by the first AC power in the primary inductor 241. In this example, an electromotive force may be generated in the secondary inductor 242 in a direction that desires to interfere with a change in the formed magnetic flux. Additionally, a magnitude of the generated electromotive force may depend on the first AC power and the turns ratio between the primary inductor 241 and the secondary inductor 242.

In this instance, each of the primary inductor 241 and the secondary inductor 242 used in the battery discharge device may be suitable to be operated when the turns ratio is equal to or greater than a predetermined value. The battery discharge device may enable voltage of power output from the output unit 260 to be greater than voltage of the first DC power discharged from the at least one battery in the accommodation unit 210. In this instance, the battery discharge device may generate output power having a smaller current value than the first DC power.

For example, the at least one battery used in the battery discharge device may be a lithium-ion battery with voltage equal to or lower than 5 V. When a discharge test is performed based on the discharge profile, a potential difference by the at least one battery may be reduced to 3 V or lower. For example, a potential difference equal to or lower than 5 V may be generated by a single battery in the accommodation unit 210. In this instance, high current, for example current equal to or higher than 1 A, may be discharged from the single battery.

The battery discharge device may transform power discharged with low voltage and high current, to power with high voltage and low current. Specifically, the battery discharge device may adjust the turns ratio between the primary inductor 241 and the secondary inductor 242, so that the second AC power generated by the transformation unit 240 may have high voltage, for example 380 V, 440 V, 500 V, and the like, even in case that the first AC power in the transformation unit 240 may have low voltage, for example voltage equal to or lower than 5 V. In this instance, each of the primary inductor 241 and the secondary inductor 242 may be suitable to be normally operated in a turns ratio that enables foregoing high step-up ratio.

As a result, the output unit 260 in the battery discharge device may add up at least one power with high voltage and low current, and may output the added power. In this instance, the battery discharge device may facilitate recycling of discharge energy, for example reducing a thickness of a power line used in wiring, and the like, by using power with high voltage and low current, instead of using power with low voltage and high current.

The rectification unit 250 in the battery discharge device may generate second DC power, based on the second AC power. Voltage of the second DC power may be higher than voltage of the first DC power. The rectification unit 250 may include at least one diode 251. The rectification unit 250 may generate the second DC power, by rectifying the second AC power that is stepped up by the transformation unit 240, using the at least one diode 251.

For example, when a single diode is used to transform the second AC power to the second DC power, the rectification unit 250 may be operated as a half-wave rectifier. Additionally, the rectification unit 250 may be operated as a center tap full-wave rectifier using two diodes. Furthermore, the rectification unit 250 may be operated as a bridge type full-wave rectifier using four diodes.

Additionally, the output unit 260 in the battery discharge device may accommodate the second DC power, may add up current of the second DC power, and may output the added current. In this instance, the accommodated second DC power may be DC power with high voltage and low current that is transformed by the transformation unit 240, and that is rectified by the rectification unit 250, as described above.

In the battery discharge device, the output unit 260 may add up the power with the high voltage and low current, and may output power having current enough to be applied as an input of an inverter. As a result, the battery discharge device may apply power with high voltage output by the output unit 260 to the inverter, and may provide regenerated power that is output from the inverter, to a micro grid, namely an AC electrical grid. Furthermore, the battery discharge device may recharge the at least one battery, using the regenerated power.

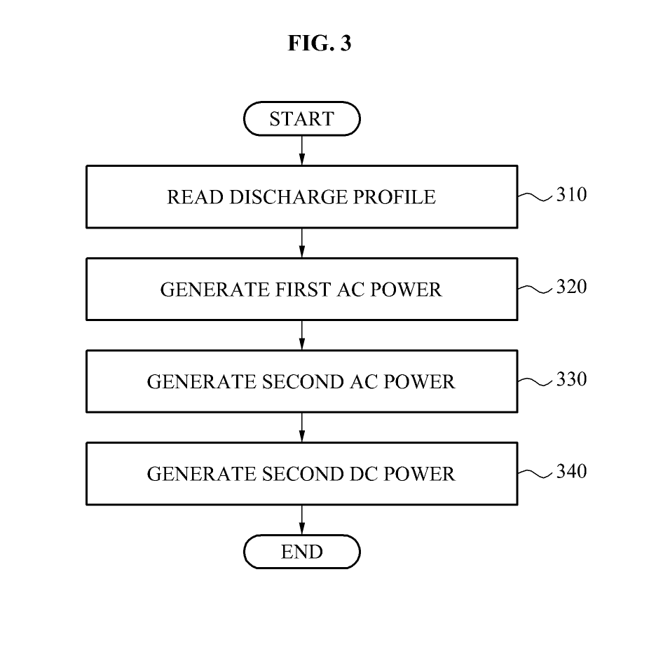

FIG. 3 is a flowchart illustrating a battery discharge method used in a discharge system that induces a discharge of a battery based on a discharge profile according to an embodiment of the present invention.

Referring to FIG. 3, the battery discharge method may include operation 310 of reading a discharge profile, operation 320 of generating first AC power, operation 330 of generating second AC power, and operation 340 of generating second DC power.

In operation 310, the discharge profile may be read from a memory storage device in which the discharge profile is stored.

In operation 320, the first AC power may be generated from first DC power that is discharged based on the discharge profile from at least one battery included in the discharge system.

Additionally, in operation 320, a magnitude of the first AC power may be controlled, using a pulse waveform generated based on the discharge profile, and using a high-current driving transistor operated by the pulse waveform.

In operation 330, the second AC power may be generated based on the first AC power. Voltage of the second AC power may be higher than voltage of the first AC power.

In operation 340, the second DC power may be generated based on the second AC power. Voltage of the second DC power may be higher than voltage of the first DC power. In this instance, a ratio of the voltage of the second DC power to the voltage of the first DC power may be equal to or greater than a predetermined value.

Technical information described with reference to FIG. 2 may equally be applied to each of operations 310 through 340 of FIG. 3 and accordingly, further descriptions thereof will be omitted.

The above-described embodiments of the present invention may be recorded in non-transitory computer-readable media including program instructions to implement various operations embodied by a computer. The media may also include, alone or in combination with the program instructions, data files, data structures, and the like. The program instructions recorded on the media may be those specially designed and constructed for the purposes of the embodiments, or they may be of the kind well-known and available to those having skill in the computer software arts. Examples of non-transitory computer-readable media include magnetic media such as hard disks, floppy disks, and magnetic tape; optical media such as CD ROM disks and DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention, or vice versa.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A battery discharge device used in a discharge system that induces a discharge of a battery based on a discharge profile, the battery discharge device comprising:
an accommodation unit to accommodate at least one battery;
a switch unit connected to the at least one battery accommodated in the accommodation unit, to generate a first alternating current (AC) power from a first direct current (DC) power discharged from the at least one battery based on the discharge profile;
a transformation unit to generate a second AC power based on the first AC power, the second AC power having a voltage higher than a voltage of the first AC power; and
a rectification unit to generate a second DC power based on the second AC power, the second DC power having a voltage higher than a voltage of the first DC power.

2. The battery discharge device of claim 1, wherein the switch unit comprises a controller to control a magnitude of the first AC power, using a pulse waveform generated based on the discharge profile.

3. The battery discharge device of claim 2, wherein the switch unit further comprises a high-current driving transistor to generate the first AC power from the first DC power, the high-current driving transistor being operated by the pulse waveform.

4. The battery discharge device of claim 1, wherein the transformation unit comprises a primary inductor and a secondary inductor, and
wherein the primary inductor accommodates the first AC power, and the secondary inductor generates the second AC power based on the first AC power and a turns ratio between the primary inductor and the secondary inductor.

5. The battery discharge device of claim 4, wherein each of the primary inductor and the secondary inductor is suitable to be operated when the turns ratio is equal to or greater than a predetermined value.

6. The battery discharge device of claim 1, further comprising an output unit to accommodate the second DC power, to add up a current of the accommodated second DC power, and to output the added current.

7. A battery discharge method used in a discharge system that induces a discharge of a battery based on a discharge profile, the battery discharge method comprising:
reading the discharge profile from a memory storage device in which the discharge profile is stored;
generating a first alternating current (AC) power from a first direct current (DC) power discharged based on the discharge profile from at least one battery included in the discharge system;
generating a second AC power based on the first AC power, the second AC power having a voltage higher than a voltage of the first AC power; and
generating a second DC power based on the second AC power, the second DC power having a voltage higher than a voltage of the first DC power.

8. The battery discharge method of claim 7, wherein the generating of the first AC power comprises controlling a magnitude of the first AC power, using a pulse waveform generated based on the discharge profile, and using a high-current driving transistor operated by the pulse waveform.

9. The battery discharge method of claim 7, wherein a ratio of the voltage of the second DC power to the voltage of the first DC power is equal to or greater than a predetermined value.

10. A non-transitory computer readable recording medium storing a program to cause a computer to:
read the discharge profile from a memory storage device in which the discharge profile is stored;
generate a first alternating current (AC) power from a first direct current (DC) power discharged based on the discharge profile from at least one battery included in the discharge system;
generate a second AC power based on the first AC power, the second AC power having a voltage higher than a voltage of the first AC power; and
generate a second DC power based on the second AC power, the second DC power having a voltage higher than a voltage of the first DC power.
